(19) United States
(12) Patent Application Publication
(10) Pub. No.: US 2009/0063600 A1
(43) Pub. Date: Mar. 5, 2009

(54) COMPUTING DEVICE AND METHOD FOR CONVERTING BETWEEN JULIAN CALENDAR DAYS AND CHINESE CALENDAR DATES

(75) Inventor: Shaun Puckrin, London (GB)

Correspondence Address: Saul Ewing LLP (Philadelphia), Attn: Patent Docket Clerk, 2 North Second St., Harrisburg, PA, 17101, US

(73) Assignee: SYMBIAN SOFTWARE LIMITED, London (GB)

(21) Appl. No.: 11/722,785

(22) PCT Filed: Dec. 21, 2005
(86) PCT No.: PCT/GB2005/004993

§ 371 Date: Oct. 14, 2008

(30) Foreign Application Priority Data
Dec. 22, 2004 (GB) 0428117.6

(51) Int. Cl. G06F 17/10; H03M 5/00

(52) U.S. Cl. 708/206; 341/55

(57) ABSTRACT

A method and computing device is provided for converting between Chinese calendar dates and Julian day numbers in any specified date range using tables stored in the memory of the computing device containing the lengths of the months and which (if any) months are leap months, together with one or more reference pairs of Julian day numbers and Chinese date.

The present invention relates to a method of converting between Julian day numbers and Chinese calendar dates in a computing device, and also to a computing device for carrying out such conversions.

The term computing device as used herein is to be expansively construed to cover any form of electrical computing device and includes, data recording devices, computers of any type or form, including hand held and personal computers such as Personal Digital Assistants (PDAs), and communication devices of any form factor, including mobile phones, smart phones, communicators which combine communications, image recording and/or playback, and computing functionality within a single device, and other forms of wireless and wired information devices, including digital cameras, MP3 and other music players, and digital radios.

The Chinese calendar is highly complex. It is not a purely solar calendar, such as the standard secular Gregorian calendar. Solar calendars are based on the yearly cycle of the sun and guarantee that the seasons will occur at around the same dates each year. The downside of a purely solar calendar is that the phases of the moon move through the month, and are not tied to particular days within a month.

Neither is the Chinese calendar a purely lunar calendar, such as the Muslim calendar. Lunar calendars are based on the monthly cycle of the moon, and guarantee that its phases will coincide with the same dates in each month. The downside of a purely lunar calendar is that the seasons move through the year and are not tied to any months.

The Chinese calendar is a lunisolar calendar. These are similar to lunar calendars in that they base their month on the cycle of the moon, so that its phases coincide with the same days each month. But, they also have a solar link, in that they require annual and seasonal events to occur around the same months in each year. This requirement is fulfilled by the insertion of leap months every two or three years to ensure that the lunar and solar components remain substantially synchronised.

The Chinese calendar is not the only calendar of this type; the Hebrew calendar used in Israel, and for traditional purposes by Jews, is also a lunisolar one. But, unlike the complex Chinese calendar, the Hebrew calendar is relatively easy for computing devices to work with. This is because it has been an independently rule-based calendar for well over 1000 years, and does not require the confirmation of any external astronomical data. For example, the lengths of the month are fixed and if a leap month is required, it will always occur prior to the first month of the year. As a result, knowing what the date might be after a certain period of time, or converting between Jewish dates and Gregorian dates, are straightforward processes.

The Chinese calendar is very different. As IBM point out (http://www-306.ibm.com/software/globalization/topics/locales/calendar_chinese.jsp)
“Unlike the Hebrew calendar, where the leap years can be calculated very simply and the intercalary month always appears in the same time of the year, the Chinese leap year and month are computed based on astronomical observations and rather complex calculations.”

The fundamental problem to be faced in working with the Chinese calendar is that its rules are not independent; the true astronomical data, rather than any simplified approximation, is supreme, and all the rules do is describe what happens when particular astronomical events occur. The key astronomical events in question are the exact time of the conjunction between the sun and the moon (known as a dark moon), and the days on which the longitude of the sun traverses an exact multiple of 30 degrees measured from the vernal equinox (known as a zhongqi).

This sounds relatively straightforward, but it is easy to underestimate the difficulties that reliance on actual astronomical events causes for calendrical operations. The data is actually extremely complex; most people do not realise that the motion of the sun and the moon is actually quite irregular and that the length of each day and the length of each month vary throughout the year (and also from one year to the next). The Chinese calendar always uses true values for such intervals (rather than mean values, such as the 24 hour day used in the Western Gregorian calendar, or the alternating 29 and 30 day months used for most years in the Hebrew calendar) when performing calendrical calculations.

This use of the true sun and the true moon makes the calculations necessary to compute the calendar in advance highly complex. It results in none of the months having fixed lengths, and means that leap months can occur at any point in the year. Because there is no simple way of knowing either the length of the current month or the name of the next month, operations that users of Western Gregorian calendars take for granted, such as finding out what the date might be six weeks from now, become quite difficult without access to and referral to precalculated calendrical tables. The same applies to the working out of conversions between Chinese calendar dates and other dates, notably Gregorian ones.

Further, the precession of the equinoxes every 25,800 years, the rotation of the earth's orbit every 110,000 years, and the slowing down of the Earth's rotation by 2 milliseconds each day means that this astronomical data is always unique and that the Chinese calendar does not ever repeat itself in relation to other, non-astronomical, calendars.

In short, there is no way of avoiding the use of complex calculations when working with arbitrary Chinese dates.

Since 1949, the Purple Mountain Observatory in Nanjing has had the responsibility for fixing dates in the Chinese calendar. However, computing devices wishing to make use of Chinese calendars are able to make use of the de-facto canonical equations developed by Edward M. Reingold and Nachum Dershowitz, which can be found in the various editions of their book “Calendrical Calculations” (Millenium edition published August 2001 by Cambridge University Press, ISBN: 0521777526).

The standard method of doing calendrical calculations on Chinese dates is by using the equivalent Julian Day as an intermediary. Not to be confused with the pre-Gregorian Julian Calendar, the Julian day is a sequential numbering for days, starting from 1 Jan. 4713 BCE (before the common era), and is widely used, notably by astronomers. It was invented by J. J. Scaliger in France shortly after the Gregorian calendar was introduced in 1582 and provides a method of uniquely referring to any historical day irrespective of calendar and without having to use negative numbers.

The Reingold and Dershowitz equations enable conversions to and from Julian day numbers and any date in any calendar. When applied to the Chinese calendar, they therefore enable conversion to and from any other calendrical system. They further enable arithmetic operations to be carried out on Chinese dates; for example, to find the number of dates between two arbitrary Chinese dates, all that is required to do is convert them into Julian days and carry out an arithmetic comparison.

For more information on the complexities of the Chinese calendar, referral is made to a paper by Helmer Aslaksen of the Department of Mathematics at the National University of Singapore entitled “The Mathematics of the Chinese Calendar”, which is to be found, together with a number of other papers by the same author, at http://www.math.nus.edu.sg/aslaksen/calendar/chinese.shtml.

Modern computing devices are known to include calendar information and data. Most notably, this is common in Personal Information Manager (PIM) type software, such as Agenda and Scheduling software. While many users of such computing devices never need to convert between different calendar systems, this is not true of users who operate in multi-cultural environments. According to IBM, “Creating successful software for worldwide use requires attention to locale details ranging from date and time to numeric formatting.”

This invention is specifically concerned with the common case of computing devices whose owners need to perform tasks such as
performing arithmetical operations on Chinese dates, such as finding out what the date might be in 30 days time
keeping consistent calendar data in both Chinese and Gregorian formats
keeping consistent calendar data in Chinese and any other calendars.

The class of such computing devices has been extended in recent years, and now includes devices such as mobile telephones and personal digital assistants (known as PDAs) as well as desktop computers. Moreover, as technologies converge, devices such as gaming machines and music players are increasingly likely also to include PIM functionality. Where users of these devices operate in places where the Chinese calendar is either the main calendar or is extensively used (e.g. in mainland China itself as well as Hong Kong, Taiwan, Singapore) both arithmetical operations on Chinese dates and quick and easy conversion to and from Western Gregorian dates is a requirement for full use of PIM functionality.

However, it is known that the Reingold and Dershowitz equations referred to above are computationally expensive since they have to model the relative position of the earth, moon and sun. Furthermore, not only do they take a long time to complete, but they also require constant referencing to large tables of astronomical data. Any computing device which implements conversion algorithms between Chinese dates and other calendars is constrained by CPU loading and memory requirements. It is further known that this causes problem for software even on desktop systems, with their relatively large computational resources in comparison to mobile telephones and PDAs; see, for example, the paper “Calendar System Facts” by Denis A. Elliott, which can be found at http://homepage.mac.com/rabbel/.cv/rabbel/Public/PDF's%20and%20Doc's/Cale ndar%20System%20Facts%20V2.pdf-link.pdf.

Elliot is the author of an Apple Macintosh program called ‘Intercal’, which computes date conversions between many different calendrical systems, and he is quite clear that “a very high number of floating-point calculations are required”. Elliot specifically mentions the large CPU overhead of the equations as one of his design constraints.

Mobile devices such as smartphones and PDAs are typically resource constrained compared to larger ‘fixed’ computing devices, such as desktop and laptop PCs, in that they have restricted operating memory, limited storage capacity, slower processors and limited amounts of battery power. However, their owners and users expect a fast sub-second response for most operations, similar to that expected from the non resource constrained desktop PCs.

It follows that using standard methods, such as the Reingold and Dershowitz equations, for operations involving Chinese calendar dates will give rise to even more serious problems for these resource constrained mobile devices than they do for fixed devices. Intensive calculations, resulting in slow performance, and the requirement for large amounts of tabular data, are therefore both significant barriers to ease of use and widespread adoption of dual-calendar capable PIM systems on such resource constrained devices.

A less CPU-intensive method of handling computing operations involving Chinese calendar data is therefore required.

It is therefore an object of the present invention to provide an improved method of handling computing operations involving Chinese calendar data that is less CPU intensive, involves no floating point operations, and does not require substantial amounts of memory. The present invention is therefore ideally and particularly suited to resource constrained mobile devices and provides significant technical benefits when used in such devices. However, as will become apparent from the detailed description below, it also offers technical benefits to the less resource constrained ‘fixed’ computing devices; not the least of these is the fact that a method without excessive CPU overhead in any computing device uses measurably less power, is quicker in operation, and is therefore more environmentally friendly.

According to a first aspect of the present invention there is provided a method of operating a computing device for converting between a range of Chinese calendar dates and Julian day numbers, the method comprising storing in a memory of the computing device information indicative of
a. the lengths of the months in each Chinese year contained in the range;
b. which, if any, months in each Chinese year contained in the range are leap months; and
c. at least one pair of Julian day numbers and Chinese date data for a common day within the range;

and causing a central processing unit (CPU) of the computing device to convert between the Chinese calendar dates and the Julian day numbers using the stored information.

According to a second aspect of the present invention there is provided a computing device arranged to operate in accordance with a method of the first aspect

According to a third aspect of the present invention there is provided an operating system for causing a computing device to operate in accordance with a method of the first aspect.

Embodiments of the present invention will now be described, by way of further example only, with reference to the accompanying drawings in which:

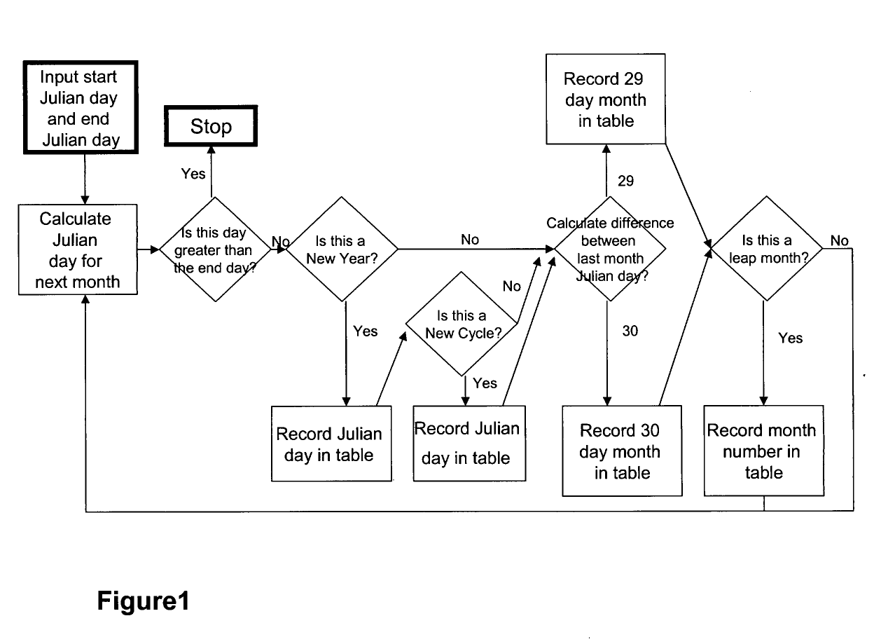

FIG. 1 shows a process for determining the 29 and 30 day months occurring in any Chinese calendar year; and

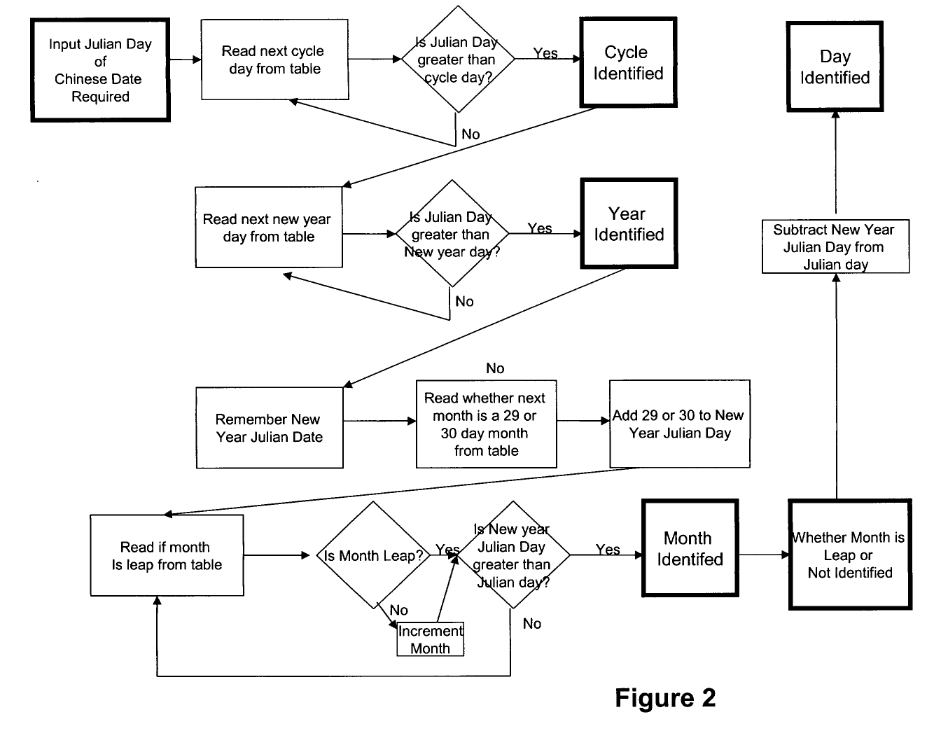

FIG. 2 shows a process for converting between Julian day numbers and Chinese calendar days in accordance with the present invention.

Firstly in order to understand this invention, it is necessary to explain why lookup tables have not been extensively used to solve the problems described above. It may have occurred to those skilled in the art that where a period of time that is of interest to a device can reasonably be specified, an alternative to performing computing on the fly with the Reingold and Dershowitz equations is to perform the calculations in advance and arrange the resulting daily Chinese calendar data in an ordered list which is kept in the device. This would enable the use of a straightforward lookup table to find out the answer to any calendrical operations involving Chinese dates.

The reason why lookup tables of this type are not a viable solution to the problem is because the volume of data is just too large.

A Chinese date consists, at minimum, of the following five independent date elements:
The cycle (each cycle is 60 years)
The year in the cycle
The month in the year
Whether the month is a leap month
The day in the month

Storing this in a conventional data structure requires 5 integers; since most computing devices make use of 32-bit integers, the requirement for a standard lookup table would be 20 bytes (5×32=160 integers) per day, or in excess of 7K bytes per year. The overhead quickly mounts up. For example, assume it is required that a device should be able, at a minimum, to handle dates in the year range 1980 to 2100 (Gregorian). This range of 120 years covers 43,830 days, which gives a conversion overhead of approximately 856K bytes of data. A common size of the ROM (Read-Only Memory) in a smartphone or PDA device is 8 megabytes; clearly, it is neither practical nor acceptable to occupy more than 10% of this valuable and crucial resource with a single calendrical table.

It is true that some optimisation of this tabular data is possible. It is possible to pack the data structure and eliminate redundant information (such as storing the complete cycle when there could be three at most in any given 120-year period). This could (at an inefficiency cost when looking up data) store the complete Chinese date in a single 32 bit integer and would therefore reduce the overhead by 80%. This gives a much lower ROM overhead of around 171 K bytes of data for the sample 120 year period given above.

While this is a considerable improvement, the fact is that space in the read-only memory (ROM) of mobile devices is at a premium. Given that the comparable overhead for non-Chinese fixed calendars is effectively zero, to adopt a table-driven approach would inevitably mean that versions of devices with Chinese calendar functionality enabled would need to have larger ROMs (leading to increased cost of production and longer boot times for devices using NAND flash technology) or reduced functionality (leading to an inferior user experience).

For these reasons, efficient table-driven approaches have not hitherto been implemented in resource-constrained mobile devices.

However, the present invention enables the reduction in the overhead of precompiled Chinese calendar information to be reduced from the original substantial ‘optimised’ overhead of 20 bytes per day to the trivial one of only 6 bytes per year, providing significant technical benefits. So, in the case of the 120 year period given above, a reduction from the original memory requirement of 856K bytes to a memory requirement of just 0.7K bytes is obtained.

This reduction of over 99.9% in the tabular overhead is clearly far superior to the previous optimised method of data packing, which can only reduce the data overhead by 80%, and provides the additional technical benefit of enabling the computationally expensive on-the-fly calculations based on the Reingold and Dershowitz equations to be dispensed with but without the necessity of including large and cumbersome data tables in the device. The technical performance of the device is, therefore, significantly improved.

A key perception behind this invention lies in understanding what is certain about the Chinese calendar and what is uncertain. Or, to put it a different way, the question which should be asked is: if the start point is a fixed Chinese date corresponding to a particular Julian day, and an attempt is then made to calculate for each succeeding day what the Chinese date corresponding to that day might be, at what point would the results of the calculations become uncertain, and what information would be needed to enable the sequence to reliably proceed?

If the sequence begins with any known Julian day and its corresponding Chinese date (i.e. the five independent data elements listed above for that date are known) it transpires that the first problem is encountered when the end of the Chinese month containing that Chinese date is approached for the first time.

There are two items of information that are required at this point; the first is how many days there are in the month (which must be either 29 days or 30 days), and the second is whether the month following is a leap month or not (either it is or it is not). Once this information is available, the sequence can carry on; it is known when to end the current month, and the number of the next month is also known.

It is worth noting that this holds true even at the end of a Chinese year; when the end of any month 12 is reached, if the next month is not a leap month, the Chinese New Year has been reached. So, the next (new) month can be reset to 1, the leap month indicator can be reset, the year can be incremented, and finally a check can be made to determine if the year has exceeded 60 (the duration of the cycle), in which case the cycle is incremented and the year is reset to 1. A process for determining the lengths of the months in each Chinese year contained in the range and which, if any, months in each Chinese year contained in the range are leap months is shown in FIG. 1. This information is stored as a table in a computing device.

There are many possible ways of encoding this information in an efficient tabular manner for use on a computing device. However, the preferred implementation disclosed in this embodiment has been designed for the Symbian OS™ operating system for mobile telephones produced by Symbian Software Ltd. An example of sample code for implementing this invention is set out below. Those skilled in the art of programming for the Symbian OS™ operating system will readily understand its purport and intent when read in conjunction with the description of the invention as now provided.

However, it is to be understood that the implementation described below, and the examples shown, are provided for illustrative purposes only. It is stressed that it is not intended for the present invention to be limited only to the Symbian OS™ operating system or to the particular implementation described below. The present invention can be implemented in many ways on many different operating systems and many different devices, including other types of computing devices, without departing from the scope of the invention.

The embodiment of the invention now described encodes the information regarding which months of the year have 29 days and which have 30 days in a single bit-mapped 16-bit integer for each year. Note that there are either 12 months in a normal year or 13 months in a leap year (only one leap month per solar year is possible). This embodiment specifies the range for the computing device in Gregorian years; an implementation for the years 1980 to 2100 is shown, since this can be related easily to the resource hungry prior art solution referred to above. The sample code shows an array of such integers in the file CALCONDATA.CPP called TCalconData::iCalConDataMonth. It can be seen from this array that there is a respective 16-bit integer for each of the 120 years in the date range under consideration.

The start of Gregorian year 1980 lies in year 55 of the first cycle of the Chinese calendar in this 120 year period; this explains the 0-55 comment attached to the first of the integers in the array, and makes the progression readily understandable. It is important to realise that the beginning of Gregorian year 1980 is the tail end of Chinese year 55, and that Chinese year 55 is not the year that begins shortly after the start of Gregorian year 1980. Since the Chinese New Year always falls in January or February, the start of Gregorian year 1980 is going to be either the last month or the penultimate month of Chinese year 55. It is also necessary to know whether Chinese year 55 is a leap year or not, whether or not the current month is a leap month, and whether the remaining months in the year have 29 or 30 days. Hence, the information attached to Gregorian year 1980 has also to refer to the Chinese calendar year that began in Gregorian year 1979.

The first integer in TCalconData::iCalConDataMonth is 38608, which corresponds to the 16 bit binary array 1001011011010000, and this holds information for Chinese year 55. In this example of the invention a binary ‘1’ bit type in this sequence is used to indicate a month of 30 days and a binary ‘0’ bit type is used to indicate a month of 29 days. Hence, this binary array, and hence the integer, indicates that the first, fourth, sixth, seventh, ninth, tenth and twelfth new months since the start of Chinese year 55 have 30 days; the remaining months in this year have 29 days. The second integer in TCalconData::iCalConDataMonth is 38320, and this holds information for Chinese year 56, which begins in Gregorian year 1980; this integer corresponds to binary array 1001010110110000. Hence, this integer indicates that the first, fourth, sixth, eighth, ninth, eleventh and twelfth months from the start of Chinese year 56 have 30 days; the remaining months in this year have 29 days.

The second array in the file CALCONDATA.CPP is called TCalconData::iCalConDataYear and consists of an array of 32-bit integers. Again, there is a respective integer for each year; the comments in the array as shown make clear that these match the data for the previous array. Each integer provides more information on the respective year. Each integer also informs as to when the respective year begins, whether there are any leap months in the year, and if so, which months.

The first integer in this array is 1881492094, giving us information for Chinese year 55 which is current at the start of Gregorian year 1980. The 28 least significant bits of this 32 bit integer hold the Julian day corresponding to the start of Chinese year 55.

1881492094 corresponds to binary array 01110000001001010100101001111110, so the binary digits 000001001010100101001111110 provide this information. These 27 least significant bits correspond to Julian day 2443902. Converting from Julian day to Gregorian date is quite straightforward and not computationally expensive. Such a conversion shows that Julian day 2443902 corresponds to Gregorian date Jan. 28, 1979, which is therefore the date of the New Year for Chinese year 55.

The four most significant bits of the 32 bit integer corresponding to 1881492094 are 0111, which corresponds to 7. The information that this encodes is which (if any) of the months in the Chinese New Year beginning on Jan. 28, 1979 are leap months. There is only ever one leap month in a Chinese year. Hence, in this case it can be seen that Chinese year 55 is a leap year and that the seventh month in that year is the leap month. It should be noted that this means the seventh month of that year is actually leap month 6 and non leap month 7 actually becomes the eighth month in that year). The second integer in the array is 2444286; this corresponds to binary sequence 00000000001001010100101111111110. In this sequence, the most significant four bits are 0000, which corresponds to zero. This means that Chinese year 56 does not contain a leap month is therefore not a leap year; the 28 least significant bits correspond to Julian day 2444286, which corresponds to Feb. 29, 1980, which was therefore the New Year for Chinese year 56.

The file CALCONDATA.H provides all the other data needed in order to interpret Chinese calendar data for the period in question; it provides the bounds of the date range concerned (from 1 Jan. 1980, which is Julian day 2444240, to 31 Dec. 2100, which is Julian day 2488434); it also informs that the first Chinese New Year in the 120 year period under consideration is Chinese year 56, the last Chinese New year in this 120 year period is year 57, that this 120 year period begins in cycle 79, and that the data covers 122 Chinese years in total.

The data provided in CALCONDATA.CPP and CALCONDATA.H are generated in advance and can be used to build a Read Only Memory (ROM) for a mobile computing device. How these data are generated is not material to this invention. They may be calculated from the Reingold and Dershowitz equations. Alternatively data from the Purple Mountain Observatory in Nanjing, or other published calendars, would also suffice.

The disclosures provided above on the construction of the data and the theory behind their workings provides is considered to provide sufficient explanation as to how these files can be used effectively in PIM type applications for a computing device. Hence, a person skilled in this art will readily be able to implement this invention to provide a technically superior substitute for the Reingold and Dershowitz equations, to thereby enable fast and highly efficient conversion between Julian days and Chinese dates, both in terms of computing device resources and time to effect conversion.

For any Chinese date in the date range represented in the tables, it is possible to jump directly to the entries in the files tables for the correct Chinese year, directly ascertain the Julian day of the New Year for that Chinese year together with the lengths in days of all the months and any relevant leap month data. Thus, to determine the Julian day and thus the Gregorian date, corresponding to any Chinese date requires a relatively small number of relatively simple arithmetic operations which can be implemented easily and quickly in the computing device.

For any Julian day in the date range, it is possible to jump directly to the entries in the tables containing the Chinese New year immediately prior to that Julian day, and once the lengths of the months and any relevant leap month information have been looked up, working out the exact Chinese date is again a relatively straightforward arithmetic operation which can be implemented quickly and without undue difficulty.

For completeness, the example of the invention set out below also provides portions of a sample program file. CHINESEUSINGTABLE.CPP contains code fragments taken from working programs written for the Symbian OS™ operating system, including routines for manipulating the data in the tables, which are provided as samples intended to illustrate how they can be used.

Those skilled in the art will readily observe that alternative implementations and further optimisations are possible; in particular, the provision of a matching Julian date for every Chinese New year is not strictly necessary, as it is possible to work these out arithmetically from the month lengths and leap month data given only a single synchronisation date on which both the Chinese date and the Julian day are known.

Together with further array packing, this optional optimisation would enable the overhead for each additional Chinese year in the date range to be reduced from 6 bytes (or 48 bits) per year, as used in the above described embodiment, to a minimum of 17 bits per year, providing further resource savings in terms of memory. However, there is some additional computing cost in unpacking a bit array of this type, and an implementation of this type would also result in operations on dates further away from the provided synchronisation point taking longer to complete that operations on dates nearer to the synchronisation point.

Hybrids, with multiple synchronisation points appearing less frequently than each year are clearly possible also. The choice of tradeoffs for any device manufactured using this invention can be left to its designers; however, the invention as defined in the appended claims is intended to apply to all such implementations, not simply the preferred embodiment described in detail above.

The following example provides the main reference table for Gregorian years 1980 to 2100. This table contains a bitmapped array indicating month lengths followed by a bitmapped array indicating any leap month and the Julian day of the Chinese New Year.

//
// CALCONDATA.CPP
//
const TUint16 TCalconData::iCalConDataMonth[ ]={

38608U, // 0 - 55
38320U, // 0 - 56
18864U, // 0 - 57
42168U, // 0 - 58
42160U, // 0 - 59
45656U, // 1 - 0
27216U, // 1 - 1
27968U, // 1 - 2
44448U, // 1 - 3
43872U, // 1 - 4
38256U, // 1 - 5
18808U, // 1 - 6
18800U, // 1 - 7
25776U, // 1 - 8
27216U, // 1 - 9
59984U, // 1 - 10
27432U, // 1 - 11
23232U, // 1 - 12
43872U, // 1 - 13
37736U, // 1 - 14
37600U, // 1 - 15
51552U, // 1 - 16
54440U, // 1 - 17
54432U, // 1 - 18
55888U, // 1 - 19
23208U, // 1 - 20
22176U, // 1 - 21
43736U, // 1 - 22
9680U, // 1 - 23
37584U, // 1 - 24
51544U, // 1 - 25
43344U, // 1 - 26
46240U, // 1 - 27
46416U, // 1 - 28
44368U, // 1 - 29
21928U, // 1 - 30
19360U, // 1 - 31
42416U, // 1 - 32
21176U, // 1 - 33
21168U, // 1 - 34
43312U, // 1 - 35
29864U, // 1 - 36
27296U, // 1 - 37
44368U, // 1 - 38
19880U, // 1 - 39
19296U, // 1 - 40
42352U, // 1 - 41
42208U, // 1 - 42
53856U, // 1 - 43
59696U, // 1 - 44
54576U, // 1 - 45
23200U, // 1 - 46
27472U, // 1 - 47
38608U, // 1 - 48
19176U, // 1 - 49
19152U, // 1 - 50
42192U, // 1 - 51
53848U, // 1 - 52
53840U, // 1 - 53
54560U, // 1 - 54
55968U, // 1 - 55
46496U, // 1 - 56
22224U, // 1 - 57
19160U, // 1 - 58
18864U, // 1 - 59
42168U, // 2 - 0
42160U, // 2 - 1
43600U, // 2 - 2
46376U, // 2 - 3
27936U, // 2 - 4
44448U, // 2 - 5
21936U, // 2 - 6
37744U, // 2 - 7
18808U, // 2 - 8
18800U, // 2 - 9
25776U, // 2 - 10
27216U, // 2 - 11
59984U, // 2 - 12
27296U, // 2 - 13
43872U, // 2 - 14
43744U, // 2 - 15
37600U, // 2 - 16
51568U, // 2 - 17
51552U, // 2 - 18
54440U, // 2 - 19
54432U, // 2 - 20
55888U, // 2 - 21
23208U, // 2 - 22
22176U, // 2 - 23
42704U, // 2 - 24
21224U, // 2 - 25
21200U, // 2 - 26
43352U, // 2 - 27
43344U, // 2 - 28
46240U, // 2 - 29
46416U, // 2 - 30
44368U, // 2 - 31
21920U, // 2 - 32
42448U, // 2 - 33
42416U, // 2 - 34
21168U, // 2 - 35
43320U, // 2 - 36
26928U, // 2 - 37
29336U, // 2 - 38
27296U, // 2 - 39
44368U, // 2 - 40
19880U, // 2 - 41
19296U, // 2 - 42
42352U, // 2 - 43
21104U, // 2 - 44
53600U, // 2 - 45
59696U, // 2 - 46
54560U, // 2 - 47
55968U, // 2 - 48
27472U, // 2 - 49
22224U, // 2 - 50
19168U, // 2 - 51
42216U, // 2 - 52
41680U, // 2 - 53
53584U, // 2 - 54
55592U, // 2 - 55

};
const TUint32 TCalconData::iCalConDataYear[ ]={

1881492094U, // 0 - 55
2444286U, // 0 - 56
2444641U, // 0 - 57
1344622275U, // 0 - 58
2445379U, // 0 - 59
2955235749U, // 1 - 0
2446117U, // 1 - 1
2446471U, // 1 - 2
1881495017U, // 1 - 3
2447209U, // 1 - 4
2447564U, // 1 - 5
1613060655U, // 1 - 6
2448303U, // 1 - 7
2448657U, // 1 - 8
1076190835U, // 1 - 9
2449394U, // 1 - 10
2418368853U, // 1 - 11
2450133U, // 1 - 12
2450487U, // 1 - 13
1613063578U, // 1 - 14
2451226U, // 1 - 15
2451580U, // 1 - 16
1344629214U, // 1 - 17
2452318U, // 1 - 18
2452672U, // 1 - 19
807759395U, // 1 - 20
2453411U, // 1 - 21
2149937413U, // 1 - 22
2454150U, // 1 - 23
2454504U, // 1 - 24
1613067594U, // 1 - 25
2455242U, // 1 - 26
2455596U, // 1 - 27
1344633230U, // 1 - 28
2456334U, // 1 - 29
2686811249U, // 1 - 30
2457073U, // 1 - 31
2457427U, // 1 - 32
1881505974U, // 1 - 33
2458166U, // 1 - 34
2458520U, // 1 - 35
1344636154U, // 1 - 36
2459258U, // 1 - 37
2459612U, // 1 - 38
807766335U, // 1 - 39
2460351U, // 1 - 40
1881508897U, // 1 - 41
2461089U, // 1 - 42
2461443U, // 1 - 43
1613074533U, // 1 - 44
2462181U, // 1 - 45
2462536U, // 1 - 46
1076204714U, // 1 - 47
2463274U, // 1 - 48
3223689101U, // 1 - 49
2464013U, // 1 - 50
2464367U, // 1 - 51
1881512913U, // 1 - 52
2465105U, // 1 - 53
2465459U, // 1 - 54
1613078549U, // 1 - 55
2466197U, // 1 - 56
2466552U, // 1 - 57
807773275U, // 1 - 58
2467291U, // 1 - 59
2149951293U, // 2 - 0
2468029U, // 2 - 1
2468383U, // 2 - 2
1613081473U, // 2 - 3
2469121U, // 2 - 4
2469475U, // 2 - 5
1076211654U, // 2 - 6
2470214U, // 2 - 7
2418389673U, // 2 - 8
2470953U, // 2 - 9
2471307U, // 2 - 10
1881519853U, // 2 - 11
2472044U, // 2 - 12
2472399U, // 2 - 13
1344650033U, // 2 - 14
2473137U, // 2 - 15
2473492U, // 2 - 16
1076215670U, // 2 - 17
2474230U, // 2 - 18
2149958232U, // 2 - 19
2474968U, // 2 - 20
2475322U, // 2 - 21
1613088413U, // 2 - 22
2476061U, // 2 - 23
2476415U, // 2 - 24
1344654050U, // 2 - 25
2477154U, // 2 - 26
2418396612U, // 2 - 27
2477892U, // 2 - 28
2478246U, // 2 - 29
1881526792U, // 2 - 30
2478984U, // 2 - 31
2479339U, // 2 - 32
1344656973U, // 2 - 33
2480077U, // 2 - 34
2480432U, // 2 - 35
1076222610U, // 2 - 36
2481170U, // 2 - 37
2149965172U, // 2 - 38
2481908U, // 2 - 39
2482262U, // 2 - 40
1613095353U, // 2 - 41
2483001U, // 2 - 42
2483355U, // 2 - 43
1344660990U, // 2 - 44
2484093U, // 2 - 45
2418403551U, // 2 - 46
2484831U, // 2 - 47
2485185U, // 2 - 48
1881533732U, // 2 - 49
2485924U, // 2 - 50
2486279U, // 2 - 51
1344663913U, // 2 - 52
2487017U, // 2 - 53
2487371U, // 2 - 54
807794093U, // 2 - 55
2488109U, // 2 - 56

0xffffffff
};

The table below shows the additional calendrical information for the Gregorian years 1980 to 2100.

//
// CALCONDATA.H
//
const TInt KFirstCycle=77;//1..n
const TInt KFirstJulianDate=2444240;
const TInt KLastJulianDate=2488434;
const TInt KFirstYear=56; //1..60
const TInt KLastCycle=79;//1..n
const TInt KLastYear=57;//1..60
const TInt KNumberOfYears=122;

These are code fragments indicating how the tables might be used to build up a series of useful calendar classes.

//
// CHINESEUSINGTABLE.cpp
//
//------------------------------------------------------

| | |
|---|---|
| // Class: | TChineseCalendar |
| // Function: | ChineseToDateTime |
| // Arguments: | TDateTime & |
| // | |
| // Comments: | This function converts the date held within |
| // | the TChineseCalendar class to a |

TDateTime format and

| | |
|---|---|
| // | places it in the TDateTime class |
| provided. | |
| // | |
| // Return: | void |

//------------------------------------------------------
void TChineseCalendar::ChineseToDateTime(TDateTime &aDT)

{
TArithmeticalDate gregDate;
TGregorianCalendar greg(iJulianDay);
greg.GregFromJulianDay(gregDate,iJulianDay);
aDT.Set(0,EJanuary,0,0,0,0,0);
aDT.SetDay(gregDate.iDay − KCalConvMonthOffsetByOne);
aDT.SetMonth((TMonth)(gregDate.iMonth −

KCalConvMonthOffsetByOne));

aDT.SetYear(gregDate.iYear);
}

//------------------------------------------------------

| | |
|---|---|
| // Class: | TChineseCalendar |
| // Function: | DateTimeToChinese |
| // Arguments: | TDateTime & |
| // | |
| // Comments: | Sets the date held in the given TDateTime |
| // | class to the TChineseCalendar class |
| // | |
| // Return: | void |

//------------------------------------------------------
void TChineseCalendar::DateTimeToChinese(const TDateTime
&aDT)

{
TArithmeticalDate gregDate;
TGregorianCalendar greg;
gregDate.iDay = aDT.Day( ) + KCalConvMonthOffsetByOne;
gregDate.iMonth = (TInt)aDT.Month( ) +

KCalConvMonthOffsetByOne;

gregDate.iYear = aDT.Year( );
iJulianDay = greg.GregToJulianDay(gregDate);
}

//------------------------------------------------------

| | |
|---|---|
| // Class: | TChineseCalendar |
| // Function: | SetDate |
| // Arguments: | TChineseDate& |
| // | |
| // Comments: | this function sets the julian day value |
| // | in the base class from the given |
| // | TChineseDate |
| // | |
| // Return: | None |

//------------------------------------------------------
TInt TChineseCalendar::SetDate(const TChineseDate &aDate)

```
{
TReal jD;
TChineseDate ChinDate = aDate;
if(!ValidDate(ChinDate))
    return KErrArgument;
if (!ChineseToFixed(aDate,jD))
    return KErrArgument;
if (jD<KFirstJulianDate || jD>KLastJulianDate)
    return KErrArgument;
iJulianDay = (TInt)jD;
return KErrNone;
}
```

//------------------------------------------------------

| | |
|---|---|
| // Class: | TChineseCalendar |
| // Function: | GetDate |
| // Arguments: | TChineseDate & |
| // | |
| // Comments: | This function Determines the chinese date |

and places it in the TChineseDate class provided for the
Julian day value held internally in the Chinese class.
//

| | |
|---|---|
| // Return: | None |

//------------------------------------------------------
TInt TChineseCalendar::GetDate(TChineseDate &aDate)

{
return ChineseFromFixed(aDate,iJulianDay);
}

//------------------------------------------------------

| | |
|---|---|
| // Class: | TChineseCalendar |
| // Function: | ChineseToFixed |
| // Arguments: | TChineseDate , TReal & |
| // | TChineseDate members start at 1 (not |
| zero) | |
| // | |
| // Comments: | This function converts a Chinese date to |

a Julian day value.
//

| | |
|---|---|
| // Return: | TBool ETrue if date valid, else EFalse |

//------------------------------------------------------
TBool TChineseCalendar::ChineseToFixed(const TChineseDate&
aDate, TReal &aJulianDay) const

| | |
|---|---|
| { | |
| TInt cycle=aDate.iCycle−KFirstCycle; | //cycle starts |

from zero

| | |
|---|---|
| TInt year=aDate.iYear−1; | //year is |

0..59

TInt days=0;
TInt targetMonth=aDate.iMonth;
//targetMonth is 1..12
TBool leap=aDate.iLeapMonth;
if (leap)

{
targetMonth++;
if (iData.GetData(cycle, year, targetMonth−1)<3)
return EFalse; //not a leap month
}

TInt month=1;
while (month<=targetMonth)

{
TInt daysFlag=iData.GetData(cycle, year, month−

1);
//We need to handle case where targetMonth is a leap month
//Eg if Chinese month==6 targetMonth will be 6
//Eg but if Chinese month 5 is a leap month, month 6 will
be 5(leap) so we need to take it into account
//BUT Eg if Chinese momth== 7(leap) we've already taken
this into account.

```
if (month==targetMonth)
    if ((leap) || (daysFlag<3))
        break;
switch (daysFlag)
    {
    case KMonthInvalid:
        return EFalse;
    case K29DayMonth:
        days+=29;
        break;
    case K30DayMonth:
        days+=30;
        break;
    case K29DayLeapMonth:
        _ASSERT_DEBUG(!leap,
```

User::Panic(KCalconPanic,ECalconChineseToFixedLeapYearInvalid));

```
        leap=ETrue;
        targetMonth++;
        days+=29;
        break;
    case K30DayLeapMonth:
        _ASSERT_DEBUG(!leap,
```

User::Panic(KCalconPanic,ECalconChineseToFixedLeapYearInvalid));

```
        leap=ETrue;
        targetMonth++;
        days+=30;
        break;
    }
month++;
}
```

//Check that if days==30, the requested month actually has
30 days

TInt checkMonth = aDate.iMonth;
if (leap)

checkMonth++; //this is the month requested by

the user

TUint daysFlag=iData.GetData(cycle, year, checkMonth−

1);

if ((aDate.iDay==30) && ((daysFlag==K29DayMonth) ||

(daysFlag==K29DayLeapMonth)))

return EFalse;

days+=aDate.iDay−1;
days+=iData.GetNewYear(cycle, year);//add the New Year
aJulianDay=days;
return ETrue;
}

//------------------------------------------------------

| | |
|---|---|
| // Class: | TChineseCalendar |
| // Function: | ChineseFromFixed |
| // Arguments: | TChineseDate &, TReal |
| // | |
| // Comments: | this function converts a Julian day value |

to a Chinese date in the form TChineseDate
//

| | |
|---|---|
| // Return: | None |

//------------------------------------------------------
TInt TChineseCalendar::ChineseFromFixed(TChineseDate &aDate,
const TReal& aJulianDay) const

{
if ((aJulianDay<KFirstJulianDate)

|| (aJulianDay>KLastJulianDate))
return KErrArgument;

TInt cycleIndex=0;
while ((cycleIndex < KLastCycle−KFirstCycle)
&& (aJulianDay >=

iData.GetNewYear(cycleIndex+1,0)))

cycleIndex++;

aDate.iCycle=cycleIndex + KFirstCycle;
TInt chineseNewYear;
TInt yearCount=0;
if (cycleIndex==0)

yearCount=KFirstYear−1;

while (yearCount<60 && aJulianDay >=

iData.GetNewYear(cycleIndex,yearCount))

yearCount++;

aDate.iYear=yearCount;
chineseNewYear = iData.GetNewYear(cycleIndex,−−

yearCount);

TInt addedNumberOfDays = 0;
TInt previousAddedNumberOfDays = 0;
TInt monthCount = 1;
aDate.iMonth = 0;
TInt monthNumber; // 0=No month exists, 1 = 29 day

month, 2 = 30 day month, 3 = 29 day leap month, 4 = 30 day
leap month

while (aJulianDay >= (chineseNewYear +

addedNumberOfDays))

{
previousAddedNumberOfDays = addedNumberOfDays;
monthNumber =

iData.GetData(cycleIndex,yearCount,monthCount−1);

```
switch (monthNumber)
    {
case KMonthInvalid:
    _ASSERT_DEBUG(0,
```

User::Panic(_L(“Calcon”),ECalconChineseFromFixedMonthInvalid
));

```
    break;
case K29DayMonth:
    addedNumberOfDays += 29;
    aDate.iMonth++;
    aDate.iLeapMonth = EFalse;
    break;
case K30DayMonth:
    addedNumberOfDays += 30;
    aDate.iMonth++;
    aDate.iLeapMonth = EFalse;
    break;
case K29DayLeapMonth:
    addedNumberOfDays += 29;
    aDate.iLeapMonth = ETrue;
    break;
case K30DayLeapMonth:
    addedNumberOfDays += 30;
    aDate.iLeapMonth = ETrue;
    break;
    }
monthCount++;
}
```

aDate.iDay = (TInt)aJulianDay − chineseNewYear−

previousAddedNumberOfDays;

aDate.iDay++;
return KErrNone;
}

const TUint KMonthMask=1<<15;
const TUint KLeapMonthShift=28;
TUint TCalconData::GetData(TInt aCycle, TInt aYear, TInt
aMonth) const

{
_ASSERT_DEBUG((aYear>=0 && aYear<=59),

User::Panic(_L(“Calcon”), ECalconGetDataYearOutOfRange));

//year range is 0..59
_ASSERT_DEBUG((aMonth>=0 && aMonth<=12),

User::Panic(_L(“Calcon”),
ECalconGetDataMonthOutOfRange));//month range is 0..12

TInt y=(aCycle*KNoOfYearsInCycle)+aYear;
y−=(KFirstYear−1); //there are KFirstYear−1 entries

missing from the head of the table

TUint16 x=iCalConDataMonth[y];
TUint mask=KMonthMask>>aMonth;
TInt flag=K29DayMonth;
if (x & mask)

flag=K30DayMonth;

TUint leapMonth=iCalConDataYear[y]>>KLeapMonthShift;
leapMonth−−;
if ((TUint)aMonth==leapMonth)

flag+=2; //--> K29/30DayLeapMonth

if ((aMonth==12) && (leapMonth==0))

flag=KMonthInvalid;//month doesn't exist

return flag;
}

TUint TCalconData::GetNewYear(TInt aCycle, TInt aYear)
const

{
_ASSERT_DEBUG((aYear>=0 && aYear<=59),

User::Panic(_L(“Calcon”),
ECalconGetNewYearYearOutOfRange));

TInt y=(aCycle*KNoOfYearsInCycle)+aYear;
y−=(KFirstYear−1);
return (iCalConDataYear[y] & 0x0fffffff);
}

//------------------------------------------------------

| | |
|---|---|
| // Class: | TChineseCalendar |
| // Function: | ValidDate |
| // Arguments: | TChineseDate & |
| // | |
| // Comments: | This function Determines whether the given |

date is a valid Chinese date
//

| | |
|---|---|
| // Return: | TBool − ETrue if date is valid, else EFalse |

//------------------------------------------------------
TBool TChineseCalendar::ValidDate(const TChineseDate
&aDate) const

{
//do some trivial checks to ensure that the date is in

the range of the lookup table

if (aDate.iYear==0 || aDate.iYear>KNoOfYearsInCycle)

return EFalse;

if (aDate.iCycle < KFirstCycle)

return EFalse;

if (aDate.iCycle==KFirstCycle && aDate.iYear <

KFirstYear)

return EFalse;

if (aDate.iCycle > KLastCycle)

return EFalse;

if ( (aDate.iCycle==KLastCycle) &&

(aDate.iYear>KLastYear))

return EFalse;

if (aDate.iDay==0 || aDate.iDay>30)

return EFalse;

return ETrue;
}

TReal TChineseCalendar::JulianDate( )

{
return iJulianDay;
}

A flow chart summarising the process used to convert between Julian day numbers and Chinese calendar dates is shown in FIG. 2.

It will be appreciated from the above description and specific example that the present invention provides significant technical benefits over current processes which provide Chinese calendar functionality, including
access to full Chinese calendar functionality, over a specified number of years, which is fast in operation, even on computing devices with constrained resources.
highly efficient in its use of computing resources such as memory and CPU usage.
no expensive and lengthy floating point mathematical calculations are involved.
reduced memory usage: to less than 0.01% of comparable current tabular look-up methods.
computing devices with full PIM functionality can more readily be provided to those working in countries where the Chinese calendar is in widespread use.
significant savings in power on the device on which it is implemented; this results in environmental benefits in terms of natural resources, and longer battery life for devices which implement it.

Although the present invention has been described with reference to particular embodiments, it will be appreciated that modifications may be effected whilst remaining within the scope of the present invention as defined by the appended claims.

1. A method of operating a computing device for converting between a range of Chinese calendar dates and Julian day numbers, the method comprising storing in a memory of the computing device information indicative of
a. the lengths of the months in each Chinese year contained in the range;
b. which, if any, months in each Chinese year contained in the range are leap months; and
c. at least one pair of Julian day numbers and Chinese date data for a common day within the range;
and causing a central processing unit (CPU) of the computing device to convert between the Chinese calendar dates and the Julian day numbers using the stored information.

2. A method according to claim 1 wherein a table comprising of bit-mapped arrays is provided to identify the lengths of the months in each Chinese year contained in the range.

3. A method according to claim 2 wherein each bit mapped array comprises a 16 bit binary array, and wherein one of the bit types of the array, and the significance of the said one bit types in the array, are used to identify months of 30 days in a respective Chinese year, and the other of the bit types of the array, and the significance of the said other of the said bit types in the array, are used to identify months of 29 days in the said Chinese year.

4. A method according to claim 3 wherein a binary 1 bit type is used to identify months of 30 days and a binary 0 bit type is used to identify months of 29 days.

5. A method according to claim 1 wherein a table of single numbers is provided to indicate the number of any leap month in each of the Chinese years in the range, with zero being used to indicate that there is no leap month in a Chinese year.

6. A method according to claim 5 wherein the single numbers are also used to identify, respectively, the Julian numbers for the years in the range.

7. A method according to claim 6 wherein each single number is provided in the form of a 32 bit binary array, and wherein the least significant 28 bits of each array are used to identify the Julian numbers and the 4 most bits of each array are used to identify which month, if any, in a Chinese year is a leap month.

8. A method according to claim 1 wherein more than one pair of Chinese dates and Julian days is provided for the years in the range, but fewer than one pair of Chinese dates and Julian days is provided per year in the range.

9. A method according to claim 1 wherein more than one pair per year of Chinese dates and Julian days is provided for the years in the range.

10. (canceled)

11. (canceled)

12. A device for operating a computing device for converting between a range of Chinese calendar dates and Julian day numbers, the device comprising means for storing in a memory of the computing device information indicative of
a. the lengths of the months in each Chinese year contained in the range;
b. which, if any, months in each Chinese year contained in the range are leap months; and
c. at least one pair of Julian day numbers and Chinese date data for a common day within the range;
and means for causing a central processing unit (CPU) of the computing device to convert between the Chinese calendar dates and the Julian day numbers using the stored information.

13. An operating system for operating a computing device for converting between a range of Chinese calendar dates and Julian day numbers, comprising computer-readable storage medium having computer-readable program code embodied in the medium, the computer-readable program code comprising computer-readable code that stores in a memory of the computing device information indicative of
a. the lengths of the months in each Chinese year contained in the range;
b. which, if any, months in each Chinese year contained in the range are leap months; and
c. at least one pair of Julian day numbers and Chinese date data for a common day within the range;
and computer-readable code that causes a central processing unit (CPU) of the computing device to convert between the Chinese calendar dates and the Julian day numbers using the stored information.
